(19) United States
(12) Patent Application Publication
(10) Pub. No.: US 2021/0265248 A1
(43) Pub. Date: Aug. 26, 2021

(54) HOUSINGS FOR SEMICONDUCTOR PACKAGES AND RELATED METHODS

(71) Applicant: SEMICONDUCTOR COMPONENTS INDUSTRIES, LLC, Phoenix, AZ (US)

(72) Inventors: Yushuang YAO, Shenzhen (CN); Qing YANG, Shenzhen (CN); Lihu HOU, Shenzhen (CN)

(73) Assignee: SEMICONDUCTOR COMPONENTS INDUSTRIES, LLC, Phoenix, AZ (US)

(21) Appl. No.: 16/796,260

(22) Filed: Feb. 20, 2020

(51) Int. Cl. H01L 23/498; H01R 12/58; H01L 21/48; H01R 43/02

(52) U.S. Cl. CPC H01L 23/49811; H01R 12/58; H01R 43/0207; H01L 21/4853; H01L 21/4803

(57) ABSTRACT

A casing for semiconductor packages that includes a plurality of press-fit pins is disclosed. Specific implementations include a shaft including a first end and a second end. The first end may include a head. The press-fit pin may include a bonding portion included at the second end. The bonding portion may include a first section extending substantially perpendicular from a longest length of the shaft. The bonding portion may also include an angled section coupled to a bonding foot. The bonding foot may be configured to be ultrasonically welded to a substrate.

### BACKGROUND

### 1. Technical Field

Aspects of this document relate generally to semiconductor packages. More specific implementations involve power semiconductor device packages.

### 2. Background

Semiconductor device packages are often installed to printed circuit boards (PCB), motherboard, or other elements. Semiconductor device packages may include elements to mount or couple the package to the PCB.

### SUMMARY

Implementations of a press-fit pin for semiconductor packages may include: a shaft including a first end and a second end. The first end may include a head. The press-fit pin may include a bonding portion included at the second end. The bonding portion may include a first section extending substantially perpendicularly from a longest length of the shaft. The bonding portion may also include an angled section coupled to a bonding foot. The bonding foot may be configured to be ultrasonically welded to a substrate.

Implementations of a press-fit pin for semiconductor packages may include one, all, or any of the following:

The shaft may form a cylinder.

The shaft may form a rectangular prism.

A surface of the bonding foot may be substantially planar with the substrate.

The press-fit pin may be configured to extend from a casing.

The press-fit pin may also be configured to be molded into the casing.

The press-fit pin may be configured to electrically couple the substrate to a printed circuit board.

Implementations of a housing for a semiconductor package may include: a casing, a plurality of connectors extending from the casing, and a plurality of press-fit pins extending from the casing. The plurality of press-fit pins and the plurality of connectors may be molded into the casing. The plurality of press-fit pins and at least a portion of each of the plurality of connectors may be configured to be ultrasonically welded to a substrate.

Implementations of a housing for semiconductor packages may include one, all, or any of the following:

Each press-fit pin of the plurality of press-fit pins may include a shaft that includes a first end and a second end. The first end may include a head.

Each press-fit pin of the plurality of press-fit pins may also include a bonding portion included at the second end. The bonding portion may include a first section extending substantially perpendicularly from a longest length of the shaft. The bonding portion may also include an angled section coupled to a bonding foot.

A surface of the bonding foot may be substantially planar with the substrate.

The shaft may form a rectangular prism.

The package may include no solder.

The press-fit pins may be only ultrasonically bonded.

Each press-fit pin of the plurality of press-fit pins may be configured to electrically couple the substrate to a printed circuit board.

Implementations of a method of forming a housing for a semiconductor package may include: molding a plurality of press-fit pins into a casing, placing the casing over a substrate, and ultrasonically bonding the plurality of press-fit pins to the substrate.

Implementations of a method of forming a housing for semiconductor packages may include one, all, or any of the following:

Each press-fit pin of the plurality of press-fit pins may be configured to electrically couple the substrate to a printed circuit board.

The press-fit pins may not be soldered.

The press-fit pins may be only ultrasonically bonded.

Each press-fit pin of the plurality of press-fit pins may include a shaft that includes a first end and a second end. The first end may include a head.

Each press-fit pin of the plurality of press-fit pins may also include a bonding portion included at the second end. The bonding portion may include a first section extending substantially perpendicular from a longest length of the shaft. The bonding portion may also include an angled section coupled to a bonding foot.

A surface of the bonding foot may be substantially planar with the substrate.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 illustrates a plurality of semiconductor packages coupled to a printed circuit board;

FIG. 2 illustrates a plurality of press-fit pins soldered to a substrate;

FIG. 3 illustrates an offset of the plurality of press-fit pins of FIG. 2;

FIG. 4 illustrates a housing coupled to a substrate of a semiconductor package;

FIG. 5 illustrates a plurality of press-fit pins molded into a casing of the package of FIG. 4;

FIG. 6 illustrates a perspective view of a press-fit pin for a semiconductor package illustrated in FIG. 5;

FIG. 7 illustrates a perspective view of a casing for the semiconductor package illustrated in FIG. 5 with the substrate removed; and

FIG. 8 illustrates a top down view of a casing for the semiconductor package with the plurality of press-fit pins and the connectors removed.

### DESCRIPTION

This disclosure, its aspects and implementations, are not limited to the specific components, assembly procedures or method elements disclosed herein. Many additional components, assembly procedures and/or method elements known in the art consistent with the intended housings for a semiconductor package will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such housings for semiconductor packages, and implementing components and methods, consistent with the intended operation and methods.

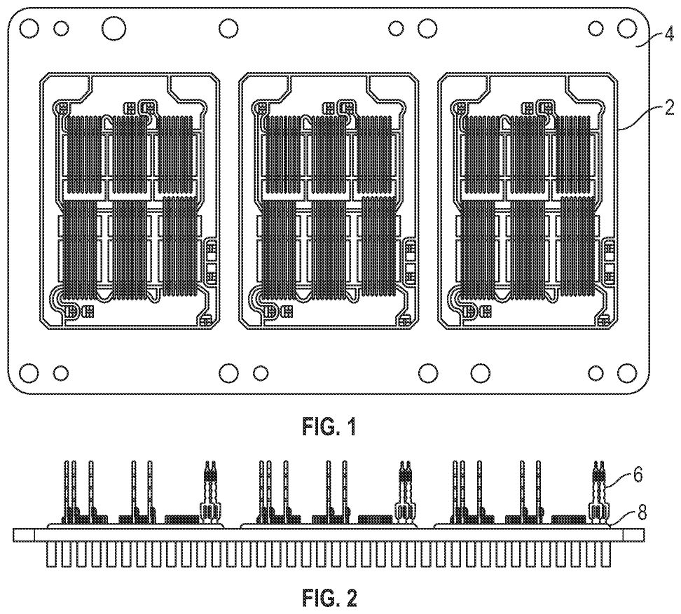

Referring to FIG. 1, a plurality of semiconductor substrates 2 coupled to a baseplate 4 is illustrated. In various implementations, press-fit pins may be used to electrically couple a substrate of each semiconductor package 2 to a printed circuit board 4 to which the assembled substrates and baseplate are coupled. In various implementations, the press-fit pins 6 electrically and mechanically couple the components of each semiconductor package 2 to external components of a motherboard, or to the printed circuit board 4, or to other external components. As illustrated, the baseplate is larger than any one of the substrates, and the substrates 2 are each separately coupled/bonded to separate locations on a largest planar surface of the baseplate. In various implementations, the substrates may be, by non-limiting example, direct bonded copper (DBC) substrates, active metal brazed (AMB) substrates, insulated metal substrate technology (IMST) substrates, laminated substrates, aluminum nitride substrates, boron nitride substrates, or any other substrate type. The baseplate in various implementations is made of, by non-limiting example, a metal, a metal alloy, one or more metal layers, a ceramic, or any other heat conductive material type.

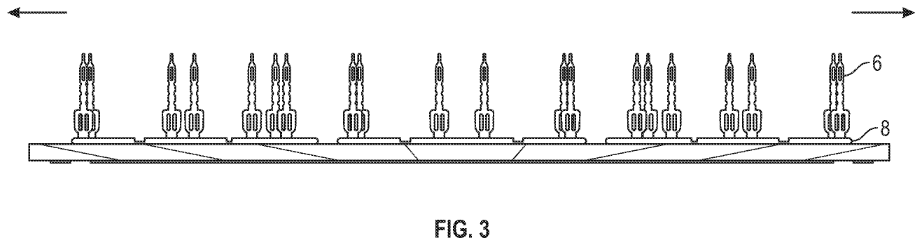

Referring to FIG. 2, a side view of a plurality of press-fit pins 6 soldered to each substrate 8 which are then coupled with a baseplate with a plurality of pins therein is illustrated. A wide variety of pin/connector types may be employed in various package implementations disclosed in this document including, by non-limiting example, press-fit pins, straight pins, flexible pins, angled pins, and any other lead connector type.

Referring to FIGS. 2 and 3, because each of the substrates is individually coupled to the baseplate, and the baseplate material may not be the same material as that used for the substrates themselves, a coefficient of thermal expansion (CTE) mismatch exists between the baseplate and the substrates. While this CTE mismatch may not cause problems for the bond between each substrate and the baseplate, since the CTE for the baseplate may be larger than for the substrates, the baseplate will tend to expand when heated more than the substrates. Since the three substrates in FIGS. 1 and 2 are separately coupled to the baseplate, the baseplate is free to expand when heated along its longest dimension without being restricted by a strip of continuous substrate material. The effect of the thermal expansion of the baseplate during manufacturing of the package is that the baseplate causes the pins on the very ends of the longest dimension of the baseplate and at each side of the shortest dimension of the baseplate to shift positions relative to each other.

Furthermore, during the package manufacturing process, the solder used to couple the press-fit pins 6 to the substrate 8 may also cause the press-fit pins 6 to float, bend or shift in position, causing an additional offset from a designed position in the finished package structure. FIG. 3 illustrates the direction of relative movement of the pins due just to expansion of the baseplate at the very ends of the longest dimension of the baseplate during the pin solder reflow step of the manufacturing process. As illustrated, the movement of the left-most pin may be up to about 0.29 mm and the movement of the right-most pin may be up to about 0.29 mm away from each other leading in various implementations to a total offset of about 0.7 mm in particular implementations. Because of this, the press-fit pin offset following the solder reflow step may make insertion/proper attachment of the press-fit pins to a printed circuit board (PCB) or motherboard difficult or impossible, as the PCB includes holes that are located at the original design location for each of the press-fit pins. Because the heads of the press-fit pins have moved during manufacturing due to the warpage/offset, insertion of the heads of the press-fit pins may be difficult or impossible. The inability to insert the pins into the PCB after manufacture results in a decrease in yield which may be as high as 20% of the manufactured packages in some implementations.

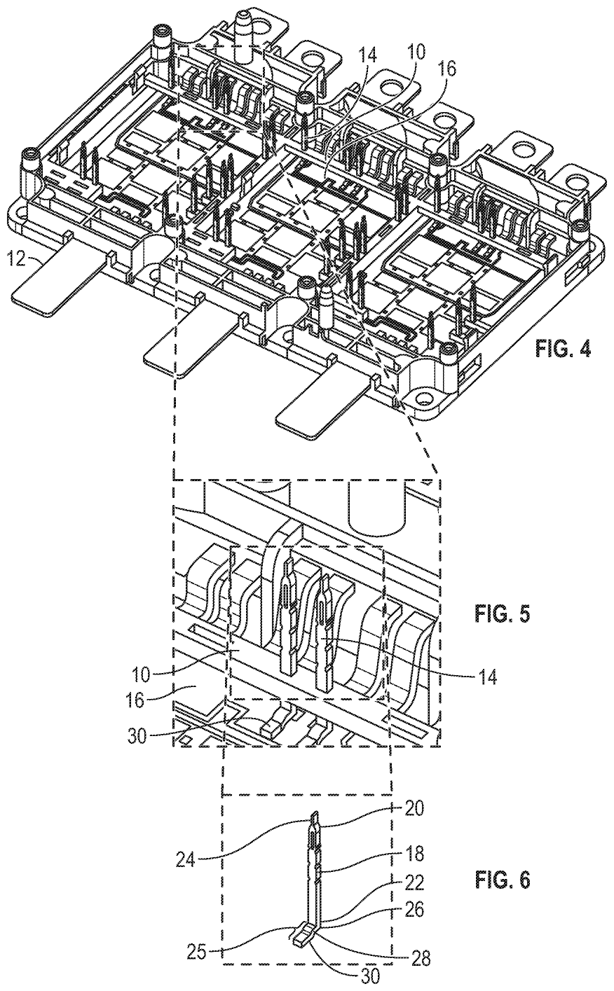

Referring to FIG. 4, a semiconductor package implementation is illustrated. In various implementations, the package includes a housing/casing 10 which forms a cavity around one or more semiconductor die coupled to a substrate. In various implementations, the cavity may be filled with an encapsulant or potting compound following complete assembly of the semiconductor package where the encapsulant or potting compound is, by non-limiting example, a resin, an epoxy, a polymer, a silicone, or any other protective material. In other implementations, however, the cavity may be left unfilled or only partially filed. In some implementations, a cover may be included with the housing (whether separately formed or integrally formed) which may include a potting compound opening therein that allows application of the encapsulant or potting compound. In other implementations, the cover may not include a potting compound opening therein. In various implementations, one or more of the electrical connectors extends through the cover, but in others, the one or more electrical connectors may not extend through the cover.

In various semiconductor package implementations, the one or more die coupled to the substrates may include, by non-limiting example, one or more power semiconductor die, one or more power metal-oxide-semiconductor field-effect transistors (power MOSFETs), one or more insulated-gate bipolar transistors (IGBTs), diodes, rectifiers, or semiconductor die with any other semiconductor device type. In the implementation illustrated in FIG. 4, three substrates are included and the casing is coupled over the three substrates though fewer or more substrates could be included in various implementations. The three substrates are coupled to a baseplate like the one illustrated in FIGS. 1-3. In various implementations, the baseplate may function as a heat sink and have various heat transfer features (pins, fins, etc.) formed into or coupled to it designed to transfer heat to a heat transfer fluid. In other implementations, the baseplate may be designed to couple to a heat sink which then contacts the heat transfer fluid. The baseplate, in some implementations, may be omitted, and the surfaces of the substrates opposite the die may be directly coupled to a heat sink or the like. The substrates may be any disclosed in this document including, by non-limiting example, a direct bonded copper (DBC) substrate, an active metal brazed (AMB) substrate, an insulated metal substrate (IMS), a ceramic substrate, and any other substrate type.

Still referring to FIG. 4, the package includes housing/casing 10, as illustrated. In various implementations, the casing includes a plurality of connectors 12 which extend from the casing 10. These connectors 12 serve as power/grounding connections for the substrates in the semiconductor package. As illustrated, and in various implementations, the connectors 12 may extend outward from the casing 10 and parallel with a longest planar dimension of the semiconductor package. In various implementations, the connectors 12 may include a flat planar surface made of any electrically conductive material, and may include openings or otherwise be shaped to mechanically and electrically connect the semiconductor package to the PCB at a first end of the connectors 12. At a second end of the connectors 12, the connectors 12 couple to the substrate through a plurality of bent sections that are coupled to locations along the edge of each substrate that place the connectors 12 in electrical connection with the various die on each substrate. Each of these bent sections may have an S shape like those illustrated in FIGS. 4 and 5. In other implementations, the bent sections may include one or more substantially 90 degree bends. In other implementations, no bent sections may be included in the connectors 12 and they may be planar as they extend through the material of the casing and bonded to the edges of the substrates. In the connector 12 implementations illustrated in FIGS. 4-5 the bent sections of the connectors are designed to allow all the bent sections to contact the surface of the substrates at the same level around the casing and at the same level as a plurality of press-fit pins 14.

As illustrated, a plurality of press-fit pins 14 extend from/into the material of the casing 10. In the implementation illustrated in FIGS. 4-5, one or more of the plurality of press-fit pins 14 and one or more of the plurality of connectors 12 are molded into the casing 10 during manufacture of the casing itself. Where the casing 10 is made using a molding technique, a jig or other device may be employed in the mold to hold the press-fit pins and/or connectors in place during the molding process. As illustrated, to accommodate the press-fit pins, one or more ribs and/or one or more supports may be included in the structure of the casing to allow the material of the casing to surround those press-fit pins. Where the press-fit pins 14/connectors 12 are molded into the material of the casing 10, the casing 10 itself physically supports the press-fit pins 14/connectors 22 at a designed location until the pins/connectors are coupled with the substrate. Because of the ability of the casing to hold the press-fit pins and/or connectors in location, the one or more of the press-fit pins 14 and at least a portion of each of the plurality of connectors 12 can be coupled to the substrates 16 via ultrasonic welding.

In various implementations, some of the press-fit pins 14 and the connectors 12 may be coupled using ultrasonic welding; in others, all of the press-fit pins 14 and the connectors 12 may be coupled using ultrasonic welding. Where all of the press-fit pins and connectors can be coupled using ultrasonic welding, none of pins/connectors are coupled using a solder, and so the soldering process, and corresponding reflow steps can be eliminated. Because of elimination of thermal processing of the substrate at the pin/connector attach step, the effects of the CTE of a baseplate used in the package may be substantially mitigated or eliminated in various implementations. Where only ultrasonic bonding is employed, in such particular implementations, the package includes no solder. As such, the press-fit pins 14 are not soldered to the substrate 16, and are only ultrasonically welded to the substrate 16. Being able to ultrasonically weld each pin does require/allow some specific structures used to couple the press-fit pins 14 to the substrate 16. Discussion of the specific structure of each press-fit pin 14, and will be described in detail below with reference to FIG. 6.

As previously discussed, a bottom surface of the substrate 16, opposite the surface of the die may, in various implementations, be coupled to one or more heat sinks, heat spreaders, heat pipes, or the like, to draw heat away from the one or more die during operation. In other various implementations, a baseplate may be used between the substrate and heat spreader/sink/pipe etc.

Referring to FIG. 5, a detail view of the package implementation of FIG. 4 illustrating a plurality of press-fit pins molded into a casing of the housing of FIG. 4 are illustrated. As illustrated, the plurality of press-fit pins 14 are molded into the casing 10. As illustrated, in an implementation of a method of manufacturing a semiconductor package, the casing 10 is placed over the substrate 16 during formation of the semiconductor package. At this point in the manufacturing process, the plurality of press-fit pins 14 are then ultrasonically bonded to the substrates 16 along with the one or more connectors The package then proceeds to additional manufacturing steps that include the placing of a housing over the package, applying a potting compound/encapsulant, or any other desired package manufacturing process. Because in various implementations of methods of manufacturing semiconductor packages like those herein which use only ultrasonic bonding, no solder is used to bond the press-fit pins 14 to the substrate 16. Because of this, the solder reflow heating step and the corresponding creation of offset of the press-fit pins caused by soldering may be reduced or eliminated entirely. In various implementations, no encapsulation compound may be used to encapsulate elements of the package after the press-fit pins 14 have been bonded thereon.

Referring to FIG. 6, a close-up view of a press-fit pin for a semiconductor package, like those illustrated in FIG. 5, is illustrated. The press-fit pin includes a shaft 18. In various implementations, the shaft 18 may form a rectangular prism, as illustrated, or it may form a cylinder, or it may form any other closed shape. As illustrated, various locking/guiding/supporting structures and/or indentations may be formed in the material of the shaft 18 of the pin 14. As illustrated, the press-fit pin also includes a first end 20 and a second end 22, as illustrated. The first end 20 of the press-fit pin includes a head 24. A wide variety of possible structures for the head 24 of the pin may be utilized in various implementations, including, by non-limiting example, a head with an opening therethrough, a head with an opening therein, an S-shaped head, a head with a rectangular prism shape, a head with a cylindrical shape, or any other press-fit pin head shape or design. As illustrated, the press-fit pin also includes a bonding portion 25 as part of the second end 22 of the press-fit pin. As illustrated, the bonding portion 25 includes a first section 26 which extends substantially perpendicularly from a longest length of the shaft 18. As illustrated, the bonding portion also includes an angled section 28 coupled to the first section 26, and also coupled to the bonding foot 30. As illustrated, a surface of a bonding foot 30 of the press-fit pin 14 is substantially planar with the substrate 16 as it couples thereto. In particular implementations, the bonding foot 30 is designed to be ultrasonically welded to a substrate. Because the angled section 28 creates a space between the end of the shaft 18 of the pin and the substrate, the ability to use ultrasonic bonding on the bonding foot 30 may be enhanced/enabled. Similar angled sections and bonding feet may be employed for the various connectors included in the package to enable their ultrasonic bonding with the substrates 16.

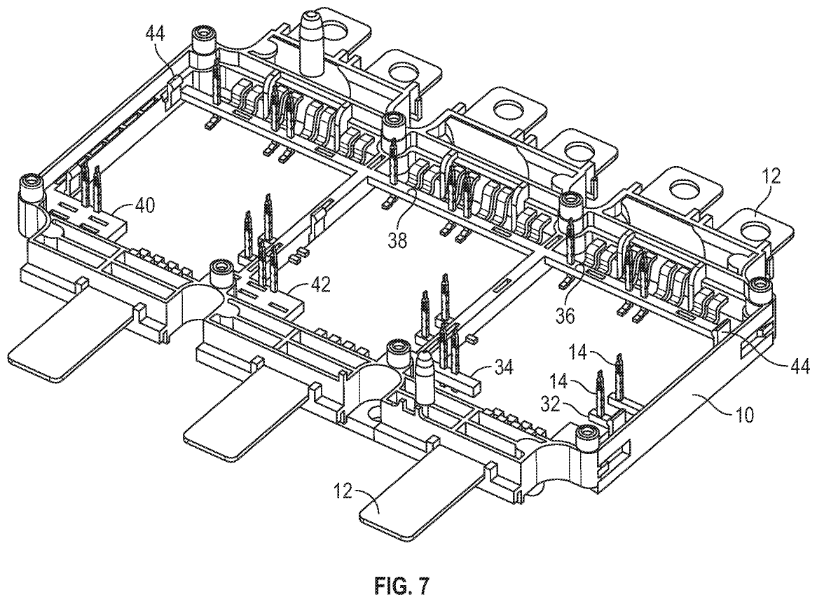

Referring to FIG. 7, an implementation of casing 10 is illustrated separated from the substrate illustrated in FIG. 4. In this implementation, the press-fit pins 14 are illustrated molded into the casing. As illustrated the press-fit pins 14 are molded into various projections 32, 34, ribs 36, 38, or grids 40, 42 that are part of the casing 10. In various implementations, the various projections, ribs, and/or grids may be present in all case designs, or they may be specifically designed to accommodate specific press-fit pin arrangements for each substrate and/or die design. Also illustrated are the connectors 12 that are molded into the material of the casing as well. Also as illustrated, locking projections 44 may be included which are designed to engage with a cover (not shown) that is placed over the openings in which the substrate and die of the package extend. This cover serves as a protective shield over the substrate and die. In some implementations, a potting compound or encapsulant may be dispensed over the surface of the substrate and die after the substrate is coupled to the package and the press-fit pins and connectors ultrasonically welded to the substrate. The cover then is placed over the potting compound or encapsulant. In other implementations, the cover may be placed over the casing first, and a potting compound opening(s) may be used to dispense the potting compound or encapsulant over the substrate and die. In other implementations, however, no potting compound or encapsulant may be used, and just the cover may be locked in place over the openings in the casing through the locking projections 44.

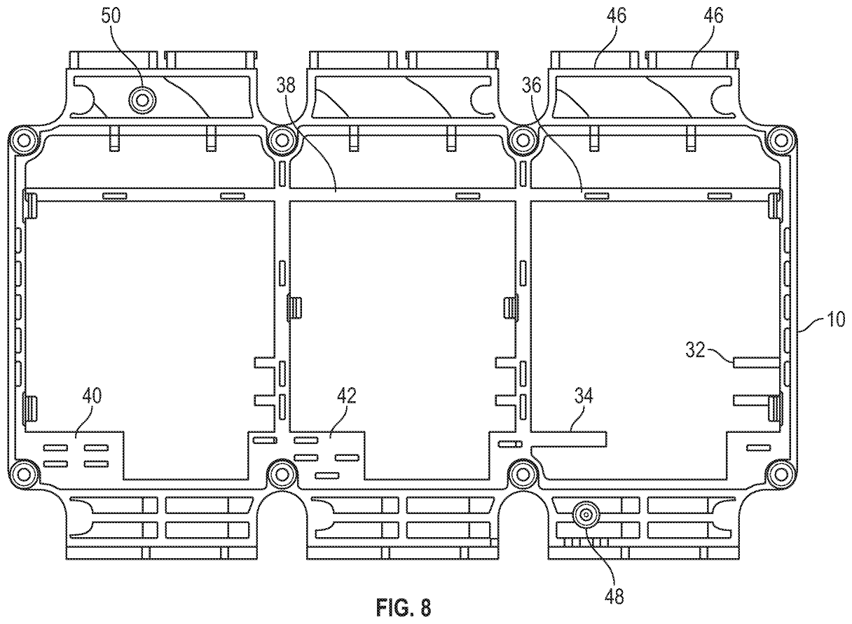

Referring to FIG. 8, a top-down view of an implementation of a casing 10 is illustrated with all of the connectors and press-fit pins removed. In this view, the outline of the projections 32, 34, ribs 36, 38, and grids 40, 42 can be better seen. Also, the locations 46 in the casing 10 where the connectors extend horizontally through the material of the casing 10 are visible in this view. The location of various alignment projections 48, 50 oriented diagonally across the length of the package is also illustrated. These alignment projections 48, 50 may be used to assist with aligning the semiconductor package with a motherboard or other socket into which the press-fit pins are inserted. While the area around each of the substrates is mostly just framed by the material of the casing 10 in the implementation illustrated in FIG. 10, in other implementations additional crossing ribs or structures could be employed that extend across or traverse each of the framed areas to support additional press-fit pins and/or other connectors molded into the crossing ribs or structures. Many different casing support designs could be devised for various press-fit pins and/or electrical connectors using the principles disclosed in this document.

In places where the description above refers to particular implementations of a casing for a semiconductor package and implementing components, sub-components, methods and sub-methods, it should be readily apparent that a number of modifications may be made without departing from the spirit thereof and that these implementations, implementing components, sub-components, methods and sub-methods may be applied to other casing for semiconductor packages.

What is claimed is:

1. A press-fit pin for a semiconductor package, comprising:
a shaft comprising a first end and a second end, the first end comprising a head;
a bonding portion comprised at the second end, the bonding portion comprising a first section extending substantially perpendicular from a longest length of the shaft, the bonding portion further comprising an angled section coupled to a bonding foot;
wherein the bonding foot is configured to be ultrasonically welded to a substrate.

2. The press-fit pin of claim 1, wherein the shaft comprises a cylinder.

3. The press-fit pin of claim 1, wherein the shaft comprises a rectangular prism.

4. The press-fit pin of claim 1, wherein a surface of the bonding foot is substantially planar with the substrate.

5. The press-fit pin of claim 1, wherein the press-fit pin is configured to extend from a casing.

6. The press-fit pin of claim 1, wherein the press-fit pin is further configured to be molded into a casing.

7. The press-fit pin of claim 1, wherein the press-fit pin is configured to electrically couple the substrate to a printed circuit board.

8. A housing for a semiconductor package, comprising:
a casing; and
a plurality of connectors extending from the casing; and
a plurality of press-fit pins extending from the casing;
wherein the plurality of press-fit pins and the plurality of connectors are molded into the casing; and
wherein the plurality of press-fit pins and at least a portion of each of the plurality of connectors are configured to be ultrasonically welded to a substrate.

9. The housing of claim 8, wherein each press-fit pin of the plurality of press-fit pins comprises a shaft comprising a first end and a second end, the first end comprising a head.

10. The housing of claim 9, wherein each press-fit pin of the plurality of press-fit pins further comprises a bonding portion comprised at the second end, the bonding portion comprising a first section extending substantially perpendicular from a longest length of the shaft, the bonding portion further comprising an angled section coupled to a bonding foot.

11. The housing of claim 10, wherein a surface of the bonding foot is substantially planar with the substrate.

12. The housing of claim 9, wherein the shaft comprises a rectangular prism.

13. The housing of claim 8, wherein the press-fit pins are only ultrasonically bonded.

14. The housing of claim 8, wherein each press-fit pin of the plurality of press-fit pins is configured to electrically couple the substrate to a printed circuit board.

15. A method of forming a housing for a semiconductor package, comprising:
molding a plurality of press-fit pins into a casing;
placing the casing over a substrate; and
ultrasonically bonding the plurality of press-fit pins to the substrate.

16. The method of claim 15, wherein each press-fit pin of the plurality of press-fit pins is configured to electrically couple with a printed circuit board.

17. The method of claim 15, wherein the press-fit pins are only ultrasonically bonded.

18. The method of claim 15, wherein each press-fit pin of the plurality of press-fit pins comprises a shaft comprising a first end and a second end, the first end comprising a head.

19. The method of claim 18, wherein each press-fit pin of the plurality of press-fit pins further comprises a bonding portion comprised at the second end, the bonding portion comprising a first section extending substantially perpendicular from a longest length of the shaft, the bonding portion further comprising an angled section coupled to a bonding foot.

20. The method of claim 19, wherein a surface of the bonding foot is substantially planar with the substrate.
